(19) United States
(12) Patent Application Publication
(10) Pub. No.: US 2002/0068415 A1
(43) Pub. Date: Jun. 6, 2002

(54) Method of fabricating a shallow trench isolation structure

(76) Inventors: Hua-Chou Tseng, Hsinchu (TW); Tony Lin, Kaohsiung Hsien (TW); Chien Chao-Huang, Hsinchu (TW)

Correspondence Address: CHARLES C.H. WU & ASSOCIATES, Suite 710, 7700 IRVINE CENTER DRIVE, Irvine, CA, 92618-3043, US

(21) Appl. No.: 09/728,677

(22) Filed: Dec. 1, 2000

(51) Int. Cl. H01L 21/76

(52) U.S. Cl. 438/435

(57) ABSTRACT

A method of fabricating a shallow trench isolation structure is disclosed. On a substrate, a pad oxide layer and a mask layer are successively formed. The pad oxide layer, the mask layer and a portion of the substrate are patterned to form a trench. After performing a rapid wet thermal process, a liner layer is formed on the exposed surface of the substrate, including the exposed silicon surface of the substrate in the trench and sidewalls and the surface of the mask layer. An oxide layer is deposited over the trench and the substrate and fills the trench. A planarization process is performed until the mask layer is exposed. The mask layer and the pad oxide layer are removed to complete the shallow trench isolation structure.

### BACKGROUND OF THE INVENTION

1. Field of the Invention

The invention relates in general to the fabrication of an integrated circuit (IC) device, and more particularly to a method of fabricating a shallow trench isolation (STI) structure.

2. Description of the Related Art

Integrated circuit (IC) usually contains thousands of metal-oxide semiconductor field effect transistors (MOSFET); for example, a dynamic random access memory (DRAM) circuit is a typical high-density IC. As integration increases, isolation structures are now of great importance in a high integration IC device. Inferior isolation structures may cause short circuit between adjacent transistors. Normally an isolation technique by forming thick field oxide (FOX), usually silicon oxide, extending on the substrate surface is used. However, charge can easily accumulate in the field oxide layer when large current flows through, further causing charge leakage and reducing the isolation ability.

One of the most common used isolation structures is local oxidation (LOCOS), which is now a mature process with high reliability and efficiency. However, there are still several drawbacks of LOCOS, including stress, consequential problems due to stress and the formation of bird's beak. In particular, the formation of bird's beaks hinders development of high integration devices. Therefore, another common isolation structure, shallow trench isolation (STI) structure, becomes more popular in high integration devices. Furthermore, STI technique can provide a global planar surface of the isolation structure, useful for the following processes.

FIGS. 1A to 1D describe a typical STI process. Referring to FIG. 1A, a pad oxide layer 102 and a silicon nitride layer 104 are sequentially formed on a provided substrate 100, using thermal oxidation and low pressure chemical vapor deposition (LPCVD), respectively.

Next, after forming a patterned photoresist layer (not shown), photolithography and etching are performed to define the STI regions. A photoresist layer is spin-coated over the substrate 100 and then patterned by exposure and development. Using the patterned photo resist layer as a mask, a shallow trench 106 is formed in the substrate 100 by anisotropic etching, which trench 106 has an inner surface 107. Afterwards, the photoresist layer is stripped.

Referring to FIG. 1B, a liner oxide layer 108 is formed on the inner surface 107 of the shallow trench 106 by thermal oxidation. The liner oxide layer 108 is formed only on the exposed silicon substrate surface in the shallow trench 106, but not on sidewalls and the surface of the LPCVD silicon nitride layer 104. An oxide layer 110 is deposited in the trench 106 by chemical vapor deposition (CVD), and then densified, for example, under 1000° C. for 10˜30 minutes.

Referring to FIG. 1C, chemical mechanical polishing (CMP) is used to planarize the CVD oxide layer 110 until the silicon nitride layer 104 is exposed, so that an oxide plug 110a is formed. Next, the silicon nitride layer 104 is first removed by hot phosphoric acid and then the pad oxide layer 102 is removed by hydrofluoric acid.

In the following process for forming P type wells or N type wells, a photoresist layer is used to cover unspecified regions, so that specified regions are exposed for ion implantation. After ion implantation, RCA cleaning solution is used to remove the photoresist. However, as shown in FIG. 1D, the RCA cleaning solution may also erode the corner of the oxide plug 110a, thus forming a recesses 111 in the comer of the oxide plug 110a. The recess 111 tends to accumulate charges and consequently induces sub-threshold leakage current, which is so-called kink effect. The undesired kink effect decreases the quality of the devices and also reduces the yield.

### SUMMARY OF THE INVENTION

It is therefore an object of the invention to provide a method of fabricating a shallow trench isolation structure with protection for the top comers of the shallow trench isolation structure, consequently preventing formation of the recess on the top comers of the STI structure. Therefore, kink effects due to charge accumulation and the sub-threshold leakage current can be avoided.

A method of fabricating a shallow trench isolation structure is disclosed. On a substrate, a pad oxide layer and a mask layer are successively formed. The pad oxide layer, the mask layer and a portion of the substrate are patterned to form a trench. After performing a rapid wet thermal process, a liner layer is formed on the exposed surface of the substrate, including the exposed silicon surface of the substrate in the trench and sidewalls and the surface of the mask layer. An oxide layer is deposited over the trench and the substrate and fills the trench. A planarization process is performed until the mask layer is exposed. The mask layer and the pad oxide layer are removed to complete the shallow trench isolation structure.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIGS. 1A to 1D are cross-sectional views showing the conventional process steps of fabricating a STI structure.

FIGS. 2A to 2D are cross-sectional views showing the process steps of fabricating a STI structure in accordance with a preferred embodiment of the invention.

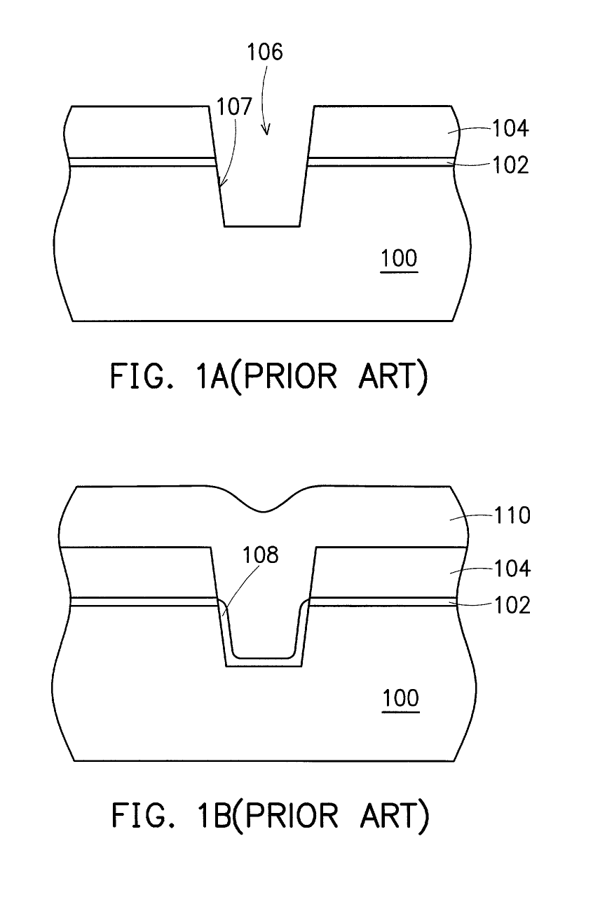

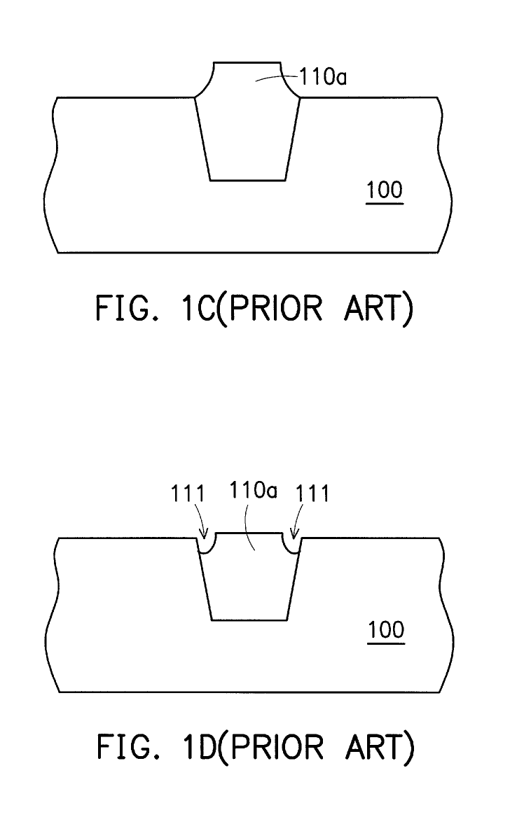

### DESCRIPTION OF THE PREFERRED EMBODIMENT

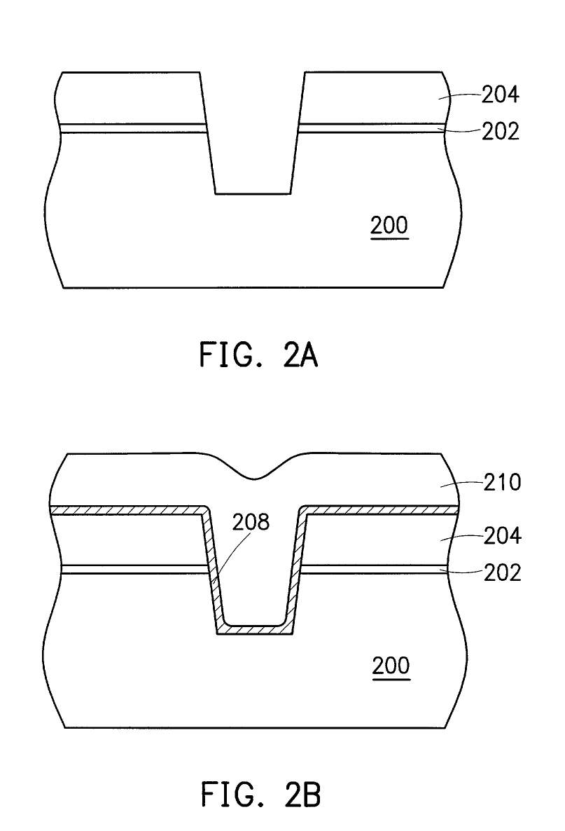

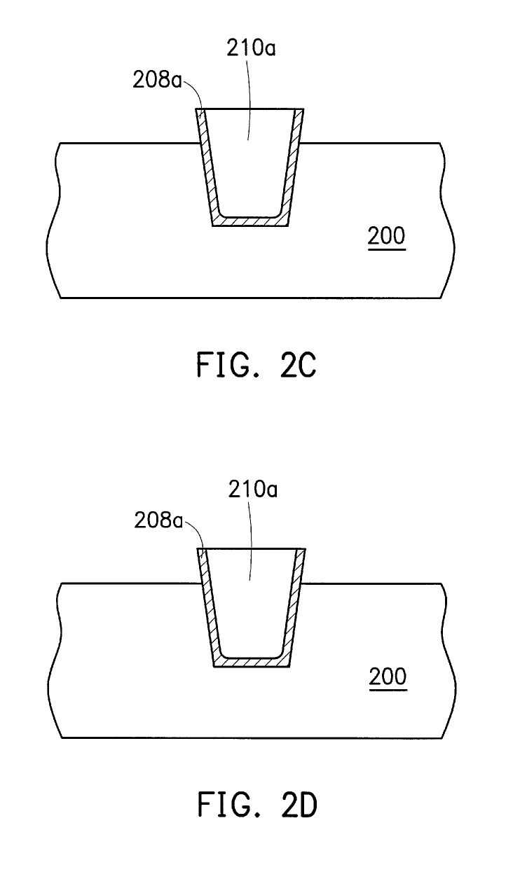

Referring to FIG. 2A, on a provided semiconductor substrate 200, a pad oxide 202 layer is formed by thermal oxidation. A silicon nitride layer 204 is formed on the pad oxide layer 202 by, for example, rapid thermal chemical vapor deposition (RTCVD) with a thickness of 1000-2000 Angstroms. Next, forming a patterned photoresist layer (not shown) is formed on the silicon nitride layer 204. Through conventional techniques of photolithography and etching, the STI regions are defined and a shallow trench 206 is formed down to the substrate. Next, the photoresist is removed.

Referring to FIG. 2B, a liner layer 208 is formed on a surface of the shallow trench 206 by, for example, rapid thermal wet oxidation at a temperature above 900° C. The liner layer 208 is formed not only on the exposed silicon substrate surface in the shallow trench 206, but also on sidewalls of the pad oxide layer 202, and sidewalls and the surface of the RTCVD silicon nitride layer 204. The liner layer 208 is a heterogeneous layer and the composition of the material for the liner layer 208 is location-dependent, including silicon oxide, silicon oxynitride or mixtures of silicon oxide and silicon oxynitride in different ratios. Preferably, the material of the liner layer 208 located on sidewalls of the RTCVD silicon nitride layer 204 consists mainly of silicon oxynitride.

An oxide layer 210 is deposited in the trench 206 to fill the trench. The oxide layer 210 is, for example, a TEOS-oxide layer formed by low-pressure chemical vapor deposition (LPCVD) with a thickness of about 5000-8000 Angstroms. The oxide layer 210 is then densified, for example, under 1000° C. for 10˜30 minutes.

Referring to FIG. 2C, chemical mechanical polishing (CMP) is used to planarize the oxide layer 210 until the silicon nitride layer 204 is exposed, so that an oxide plug 210a is formed. A portion of the liner layer 208 is removed by CMP to form a liner layer 208a. Next, the silicon nitride layer 204 is first removed by hot phosphoric acid and then the pad oxide layer 202 is removed by hydrofluoric acid. Because the liner layer 208 is formed on sidewalls and the surface of the RTCVD silicon nitride layer 204, even after planarization, the side surface of the oxide plug 210a is protected by the liner layer 208a. In the following process for forming P type wells or N type wells, a photoresist layer is used to cover unspecified regions, so that specified regions are exposed for ion implantation. After ion implantation, RCA cleaning solution is used to remove the photoresist. As shown in FIG. 2D, the remained liner layer 208a protects the comers of the oxide plug 210a. Because the liner layer 208a located on sidewalls of the RTCVD silicon nitride layer 204 consists mainly of silicon oxynitride, the liner layer 208a located on sidewalls of the RTCVD silicon nitride layer 204 is more resistant to etching by the RCA cleaning solution. Therefore, the RCA cleaning solution will not erode the comers of the oxide plug 210a, thus preventing formation of a recess in the comer of the oxide plug 210a. As a result, it avoids charge accumulation and consequently prevents kink effect, further raising the quality of the devices and the yield.

It is therefore apparent that the present includes at least the following characteristics: forming a liner layer more resistant to the RCA cleaning solution on the side surface of the oxide plug for the isolation structure, thus preventing the recess forming on the comers of the oxide plug. Consequently, kink effect is improved and leakage current is reduced, further enhancing the performance of the device.

While the invention has been described by way of example and in terms of a preferred embodiment, it is to be understood that the invention is not limited thereto. To the contrary, it is intended to cover various modifications and similar arrangements and procedures, such as the formation of a multiple voltage transistor. The scope of the appended claims therefore should be accorded the broadest interpretation so as to encompass all such modifications and similar arrangements and procedures.

What is claimed is:

1. A method of fabricating a shallow trench isolation structure, comprising:
providing a substrate;
forming a pad oxide layer and a mask layer successively on the substrate;
patterning the pad oxide layer, the mask layer and a portion of the substrate to form a trench;
performing a rapid wet thermal process to form a liner layer on an exposed surface of the substrate, including an exposed silicon surface of the substrate in the trench, sidewalls of the pad oxide layer and sidewalls and a surface of the mask layer;
forming an oxide layer over the trench and the substrate and filling the trench;
performing a planarization process until the mask layer is exposed; and
removing the mask layer and the pad oxide layer to complete the shallow trench isolation structure.

2. The method as claimed in claim 1, wherein the step for forming the pad oxide layer includes a thermal oxidation process.

3. The method as claimed in claim 1, wherein the oxide layer comprises a TEOS-oxide layer.

4. The method as claimed in claim 1, wherein the step for forming the oxide layer includes low-pressure chemical vapor deposition.

5. The method as claimed in claim 1, wherein the step for forming the mask layer comprises forming a silicon nitride layer by rapid thermal chemical vapor deposition.

6. The method as claimed in claim 1, wherein the step for forming the trench comprises anisotropic etching.

7. The method as claimed in claim 1, wherein the planarization process includes chemical mechanical polishing.

8. The method as claimed in claim 1, wherein a material of the liner layer formed on the sidewalls of the mask layer comprises mainly silicon oxynitride.

9. A method of fabricating a shallow trench isolation structure, comprising:
providing a substrate;
forming a pad oxide layer and a mask layer successively on the substrate;
patterning the pad oxide layer, the mask layer and a portion of the substrate to form a trench;
forming a liner layer on a exposed silicon surface of the substrate in the trench, sidewalls of the pad oxide layer and sidewalls and a surface of the mask layer and forming a planarized oxide plug to fill the trench; and
removing the mask layer and the pad oxide layer to complete the shallow trench isolation structure.

10. The method as claimed in claim 9, wherein the step for forming a liner layer on a exposed silicon surface of the substrate in the trench and sidewalls and a surface of the mask layer and forming a planar oxide plug to fill the trench further comprises the following steps:
forming an oxide layer over the trench and the substrate and filling the trench; and
performing a planarization process until the mask layer is exposed to form the planar oxide plug.

11. The method as claimed in claim 9, wherein the step for forming the liner layer comprises a rapid wet thermal process.

12. The method as claimed in claim 9, wherein a material of the liner layer formed on the sidewalls of the mask layer comprises mainly silicon oxynitride.

13. The method as claimed in claim 9, wherein the step for forming the pad oxide layer includes a thermal oxidation process.

14. The method as claimed in claim 10, wherein the oxide layer comprises a TEOS-oxide layer.

15. The method as claimed in claim 10, wherein the step for forming the oxide layer includes low-pressure chemical vapor deposition.

16. The method as claimed in claim 9, wherein the step for forming the mask layer comprises forming a silicon nitride layer by rapid thermal chemical vapor deposition.

17. The method as claimed in claim 9, wherein the step for forming the trench comprises anisotropic etching.

18. The method as claimed in claim 10, wherein the planarization process includes chemical mechanical polishing.

19. A method of fabricating a shallow trench isolation structure, comprising:
providing a substrate;
forming a pad oxide layer on the substrate;
forming a silicon nitride layer by rapid thermal chemical vapor deposition on the pad oxide layer;
patterning the pad oxide layer, the silicon nitride layer and a portion of the substrate to form a trench;
performing a rapid wet thermal process to form a liner layer on an exposed surface of the substrate, including an exposed silicon surface of the substrate in the trench, sidewalls of the pad oxide layer and sidewalls and a surface of the silicon nitride layer;
forming an oxide layer over the trench and the substrate and filling the trench;
performing a planarization process until the silicon nitride layer is exposed; and
removing the silicon nitride layer and the pad oxide layer to complete the shallow trench isolation structure.

20. The method as claimed in claim 19, wherein the planarization process includes chemical mechanical polishing.
